(19) United States
(12) Patent Application Publication
(10) Pub. No.: US 2008/0142986 A1
(43) Pub. Date: Jun. 19, 2008

(54) Semiconductor integrated circuit

(75) Inventors: Koji Yasumori, Tokyo (JP); Hisayuki Nagamine, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory Inc., Tokyo (JP)

(21) Appl. No.: 12/000,611

(22) Filed: Dec. 14, 2007

(30) Foreign Application Priority Data
Dec. 19, 2006 (JP) 2006-340791

(51) Int. Cl. H01L 23/488

(52) U.S. Cl. 257/773; 257/E23.023

(57) ABSTRACT

A conductive pattern is provided in the vicinity of a bonding pad and connection is made therebetween using pillar-shaped leading interconnections. By providing an insulating film, in addition to the pillar-shaped leading interconnections, between the conductive pattern and the bonding pad, the impact at the time of bonding is weakened to thereby suppress offset of the conductive pattern. According to the pad structure of this invention, it becomes possible to reduce the pattern design standard around the bonding pad and thus a small-chip-size semiconductor integrated circuit is obtained.

This application is based upon and claims the benefit of priority from Japanese patent application No. 2006-340791, filed on Dec. 19, 2006, the disclosure of which is incorporated herein in its entirety by reference.

### BACKGROUND OF THE INVENTION

This invention relates to a semiconductor integrated circuit and, in particular, relates to the layout and structure of a bonding pad and its peripheral interconnection.

A semiconductor integrated circuit has a plurality of connection terminals (leads) for data transfer with an external system. By connecting these connection terminals to bonding pads provided on a semiconductor substrate by wire bonding, an internal circuit of the semiconductor integrated circuit and the external system are connected together. Since, in this wire bonding, a wire is mechanically bonded to the bonding pad under pressure, the bonding pad is required to have a large size. Further, the pad peripheral standard that is much more lenient than the normal process minimum standard is applied to the pad peripheral region, i.e. the region around the pad, in order to prevent damage to a neighboring internal pattern. In this manner, the lenient pad peripheral standard is used as the pad peripheral layout design standard in order to prevent damage to the internal pattern at the time of the bonding to thereby ensure the reliability.

Related bonding pad structures will be described. FIG. 1 is a plan view of a bonding pad portion. FIG. 2 is a plan view of a single-layer aluminum structure bonding pad portion and FIGS. 3 and 4 are sectional views taken along line III-III′ and line IV-IV′ in FIG. 2, respectively. FIG. 5 is a plan view of a two-layer aluminum structure bonding pad portion and FIGS. 6 and 7 are sectional views taken along line VI-VI′ and line VII-VII′ in FIG. 5, respectively. In the following description, a lower-layer aluminum interconnection will be referred to as a first aluminum layer and an upper-layer aluminum interconnection as a second aluminum layer. However, the lower- and upper-layer aluminum interconnections are not particularly limited to those shown in the figures, i.e. an arbitrary aluminum interconnection may be a lower layer and an aluminum interconnection formed thereover may be an upper layer.

In FIG. 1, a second aluminum layer 4 is formed in a pad region 10, a leading region 11 and a pad peripheral region (as a pad periheral interconnection 9). The pad region 10 includes a bonding pad 1 which comprises a part of the second aluminum layer 4 exposed at a cover opening 2 where an insulating film on the surface of the second aluminum layer 4 is removed. The leading region 11 is for leading an internal circuit connecting interconnection 7 which comprises a part of a first aluminum layer 3. The second aluminum layer 4 of the pad region 10 is connected to the first aluminum layer 3 being a lower layer through contacts 5 in the leading region 11 and is further connected to an internal circuit through the internal circuit connecting interconnection 7. The pad peripheral interconnection 9 is disposed at a distance D around the pad region 10 and the leading region 11. In this description, a region including the pad region 10 and the leading region 11 may be sometimes collectively referred to as a bonding pad (simply a pad) or a bonding pad portion (simply a pad portion).

A single-layer aluminum structure bonding pad 1 shown in FIGS. 2, 3, and 4 comprises only a single aluminum layer (a second aluminum layer 4 in the figures). An insulating film 6 on the surface of the aluminum layer is removed at a cover opening 2, so that the surface of the aluminum layer is exposed. The second aluminum layer 4 is connected to a first aluminum layer 3 through contacts 5 in a leading region 11 and is further connected to an internal circuit through an internal circuit connecting interconnection 7.

In a two-layer aluminum structure bonding pad 1 shown in FIGS. 5, 6, and 7, two layers, i.e. a first aluminum layer 3 and a second aluminum layer 4, are connected to each other through first contacts 5-1. An insulating film 6 on the surface of the second aluminum layer 4 is removed at a cover opening 2, so that the surface of the second aluminum layer 4 is exposed. The second aluminum layer 4 is connected to the first aluminum layer 3 through second contacts 5-2 in a leading region 11 and is further connected to an internal circuit through an internal circuit connecting interconnection 7. The first aluminum layer 3 includes a part disposed just under the second aluminum layer 4. However, apart from the part of the first aluminum layer 3 just under the second aluminum layer 4, another part of the first aluminum layer 3 forms the internal circuit connecting interconnection 7 connected to the second contacts 5-2 in the leading region 11.

As shown in FIGS. 5, 6 and 7, the first aluminum layer 3 and the second aluminum layer 4 are connected together through the large number of contacts 5-1 in a pad region 10. Adhesion is improved by connecting the layers through the large number of contacts 5-1, thereby making the bonding condition uniform. Further, the internal circuit connecting interconnection 7 is provided in the leading region 11. The reason for forming the bonding pad into the two-layer aluminum structure as described above is that since the second aluminum layer 4 is connected to the first aluminum layer 3 through the large number of contacts 5-1, the adhesion is high so that the bonding impact can be resisted. Therefore, as compared with the single-layer aluminum structure bonding pad shown in FIGS. 2, 3, and 4, the multilayer aluminum structure bonding pad shown in FIGS. 5, 6, and 7 is excellent in suppressing offset or stripping of the aluminum layer at the time of wire bonding.

The leading region 11 is designed in consideration of the quality of reliability such as the antenna standard for preventing charge-up breakdown in fabrication and the electrostatic discharge (ESD) withstand voltage standard for preventing electrostatic breakdown. The antenna standard is a standard for preventing breakdown of transistor gates due to charge storage caused by plasmas in fabrication. In the fabrication, plasma devices are used in patterning processes for interconnections, contacts, and so on. Since plasmas are produced in the plasma devices, a large amount of charge is stored in the processing interconnections, contacts, and so on. Accordingly, there are those instances where gate insulating films of transistors connected to the interconnections are subjected to breakdown due to the discharge of the stored charge.

In view of this, the lower aluminum layer 3 is divided into the pad region 10 and the leading region 11. The leading region 11 is provided to thereby provide the internal circuit connecting interconnection 7 for connection to the internal element. The path for allowing the charge to escape is formed by switching to the internal circuit connecting interconnection 7, thereby satisfying the antenna standard. The ESD withstand voltage standard is intended to prevent electrostatic breakdown. In view of this, the large number of contacts 5-2 connected to the internal circuit connecting interconnection 7 are disposed in the leading region 11 for forming the path where a large amount of current flows from the bonding pad.

In this manner, the pad portion is provided with the leading region in consideration of reliability and, further, the bonding pad peripheral region is designed such that the pad peripheral aluminum interconnection is arranged at a distance large enough to prevent breakdown of the internal pattern. Accordingly, the current situation is such that despite the recent progress in miniaturization, only the bonding pad peripheral region is not reduced in size. In addition, the number of pads has been increasing due to an increase in the number of pins of a semiconductor integrated circuit and thus the ratio of the pad area occupying a chip has been increasing. Consequently, a reduction in size of the bonding pad peripheral region is an essential step toward a reduction in chip size.

As prior patent documents about the bonding pad peripheral region, there are the followings:

Japanese Examined Patent Application Publication (JP-B) No. Hei 06-91127 discloses a technique of forming a through hole in an insulating film between a leading interconnection from a pad and a pad peripheral interconnection, thereby relaxing the stress at the time of bonding.

Japanese Unexamined Patent Application Publication (JP-A) No. 2002-134509 and Japanese Unexamined Patent Application Publication (JP-A) No. 2001-156070 each disclose a technique of connecting together a lower aluminum layer and an upper aluminum layer, forming a pad, through a large number of contacts, thereby relaxing the stress at the time of bonding.

Japanese Unexamined Patent Application Publication (JP-A) No. 2004-247659 discloses a technique of providing, around a pad, an input terminal capacitance and an input resistance that are independently adjustable.

These techniques described in the prior patent documents are equivalent to the foregoing related pad structures. A further reduction in size of the bonding pad peripheral region is required for reducing the chip size and the development therefor is demanded.

### SUMMARY OF THE INVENTION

As described above, the reduction in size of the bonding pad peripheral region is the essential step to be made. The reduction in size of the bonding pad peripheral region is enabled by reducing the distance between the pad and the pad peripheral aluminum interconnection. Currently, the wire bonding direction of a bonder is not fixed. Consideration is given to the case where bonding is applied to the bonding pad 1 as shown in FIG. 8A. The stress is applied to the bonding pad 1 in a direction of arrow due to an impact at the time of the bonding. Therefore, the impact is transmitted to the bonding pad 1, so that the pad region 10 is moved.

The impact at the time of the bonding is directly transmitted to the leading region 11. Accordingly, as shown in FIG. 8B, there arises a problem that the aluminum pattern is offset to cause a short circuit with the pad peripheral aluminum interconnection 9. This problem causes disadvantages such as a reduction in assembly yield and occurrence of market claims. In order to avoid this problem, it is necessary that the distance between the bonding pad and the peripheral aluminum pattern be set sufficiently large. Consequently, the size reduction of the bonding pad peripheral region cannot be achieved.

On the other hand, there are recently some product catalogs defining the maximum and minimum terminal capacitance values. Accordingly, it is necessary to adjust a terminal capacitance value within the standard value range. However, a rising waveform of a signal input into the pad portion differs depending on the position where a terminal capacitance is added, even with the same terminal capacitance value. The rising waveform of the input signal is better as the capacitance is added at the position closer to the bonding pad portion. There are some high-speed product catalogs describing the slope of such a signal waveform.

Hereinbelow, the reason why it is better to add the capacitance at the position closer to the bonding pad portion will be explained with reference to FIGS. 9 and 10. FIG. 9 is an equivalent circuit from a bonding pad 1 to an input initial-stage circuit 16. The bonding pad 1 is connected to the input initial-stage circuit 16 through an aluminum interconnection resistance R1, a protective circuit 15, an aluminum interconnection resistance R2, a poly resistance Rp, and an aluminum interconnection resistance R3. A design in which the rising waveform of a signal input into the bonding pad portion is excellent or not is related to the layout of resistance and capacitance up to the input initial-stage circuit 16.

The signal waveform is determined by a time constant, i.e. the product of resistance and capacitance in a transmission line. In FIG. 9, the resistance components are the aluminum interconnection resistance R1, the protective circuit 15, the aluminum interconnection resistance R2, the poly resistance Rp, and the aluminum interconnection resistance R3. If the capacitance is added subsequent to these resistances, the time constant becomes larger. If the capacitance is added prior to these resistances, i.e. between the aluminum interconnection resistance R1 and the bonding pad 1, i.e. at the bonding pad portion, the time constant becomes smaller. Accordingly, if the capacitance is added at the bonding pad portion, the rise of a signal is better with a less signal delay.

In FIG. 10, a capacitance element region 13 is provided in an internal element region 12 and, further, a terminal capacitance region 14 is provided in a pad region 10, thereby forming a terminal capacitance. The terminal capacitance is formed along sides of the pad region 10 except its side adjacent to a leading region 11. If the capacitance can be further added in the terminal capacitance region 14 of the pad region 10, it is possible to reduce the capacitance element region 13 of the internal element region 12. This makes it possible to effectively use the internal element region 12 and, thus, a reduction in chip size can be achieved.

The protective circuit 15, the aluminum interconnection resistance R2, the poly resistance Rp, and the aluminum interconnection resistance R3 shown in FIG. 9 are disposed in the capacitance element region 13. The aluminum interconnection resistance R1 is an aluminum interconnection resistance in the leading region 11 and an internal circuit connecting interconnection 7. In view of the foregoing two points, it is preferable that the terminal capacitance be provided in the terminal capacitance region 14 of the pad region 10. As a method of forming the pad terminal capacitance, there is considered a method of forming it using a transistor gate capacitance, a diffusion layer capacitance, or a low-resistance interconnection such as an aluminum interconnection. However, any method has a drawback that the area increases.

Among them, it is considered best to form the capacitance using the aluminum interconnection. In the case of the capacitance using the aluminum interconnection, the antenna standard for preventing charge-up breakdown and the ESD withstand voltage standard for preventing electrostatic breakdown can be easily satisfied and thus the reliability is high. Further, it can be pointed out that the capacitance dependence of voltage and the process variation are small. However, in order to provide the capacitance using the aluminum interconnection in the terminal capacitance region 14 of the pad region 10, a design should be made so as to provide a sufficient distance from the aluminum interconnection for preventing the foregoing aluminum pattern short circuit. As a result, there is also a drawback that the capacitance possessed by the aluminum interconnection itself and the side-wall capacitance with the counter-electrode aluminum pattern are small.

Next, the technique of providing the terminal capacitance in the pad region described in Japanese Unexamined Patent Application Publication (JP-A) No. 2004-247659 will be explained with reference to FIG. 11. The aluminum interconnection capacitance comprises a capacitance of a bonding pad 1 itself and a side-wall capacitance between a capacitance pad interconnection 18 and a capacitance counter-electrode interconnection 19. The capacitance pad interconnection 18 is a comb-shaped interconnection having teeth each extending from the bonding pad 1 toward a pad peripheral interconnection 9. The capacitance counter-electrode interconnection 19 serving as a counter electrode is a comb-shaped interconnection having teeth each extending from the pad peripheral interconnection 9 toward the bonding pad 1. The teeth of the capacitance pad interconnection 18 and the capacitance counter-electrode interconnection 19 are staggered in zigzag. The capacitance pad interconnection 18 and the capacitance counter-electrode interconnection 19 are the same-layer aluminum interconnections, wherein the distance between the facing teeth of the comb-shaped interconnections 18 and 19 is given by D3 and the distance between the tip of the tooth of the comb-shaped interconnection 18, 19 and the opposed interconnection is given by D2. The capacitance between the capacitance pad interconnection 18 and the capacitance counter-electrode interconnection 19 is determined by the distances D2 and D3.

Currently, the distances D2 and D3 are set large because of the pad peripheral region. By reducing these distances, an increase in capacitance value is expected. By increasing the terminal capacitance formed at the pad portion, it becomes possible to reduce the capacitance element region 13 of the internal element region 12 described with reference to FIG. 10. By reducing the capacitance element region 13, the chip size reduction is achieved. It becomes possible to reduce the distance between the bonding pad and the pad peripheral interconnection and further to form the terminal capacitance in the pad region.

It is an object of this invention to provide a bonding pad and a semiconductor integrated circuit that can reduce the distance between the bonding pad and a pad peripheral interconnection to thereby reduce the chip size. Further, it is another object of this invention to provide a bonding pad and a semiconductor integrated circuit that can reduce the distance between interconnections in a region around the bonding pad, i.e. the bonding pad peripheral region, to form a terminal capacitance, thereby reducing the chip size.

For accomplishing the foregoing objects, this invention basically employs the techniques which will be described hereinbelow. It is needless to say that the invention also includes those applied techniques that can be variously changed without departing from the principle of the invention.

According to an aspect of this invention, a semiconductor integrated circuit includes a bonding pad, a conductive pattern disposed in the vicinity of the bonding pad, and a leading interconnection connecting the conductive pattern to the bonding pad.

In the semiconductor integrated circuit, an insulating film may be provided, in addition to the leading interconnection, between the conductive pattern and a side of the bonding pad so as to suppress offset of the conductive pattern.

The conductive pattern may have a length substantially equal to that of the side of the bonding pad and may be disposed parallel to the side of the bonding pad.

The conductive pattern may be further connected to an internal circuit connecting interconnection connected to an internal circuit and the leading interconnection may have a width equal to or greater than that of the internal circuit connecting interconnection.

The semiconductor integrated circuit may include a counter conductive pattern in the vicinity of the conductive pattern to form a terminal capacitance between the conductive pattern and the counter conductive pattern.

The conductive pattern and the counter conductive pattern may be each arranged in a comb shape having teeth so that the teeth of the conductive pattern and the teeth of the counter conductive pattern are staggered in zigzag.

### BRIEF DESCRIPTION OF THE DRAWINGS

FIG. 1 is a plan view of a bonding pad portion;

FIG. 2 is a plan view of a single-layer aluminum structure bonding pad portion;

FIG. 3 is a sectional view, taken along line III-III′, of the single-layer aluminum structure bonding pad portion in FIG. 2;

FIG. 4 is a sectional view, taken along line IV-IV′, of the single-layer aluminum structure bonding pad portion in FIG. 2;

FIG. 5 is a plan view of a two-layer aluminum structure bonding pad portion;

FIG. 6 is a sectional view, taken along line VI-VI′, of the two-layer aluminum structure bonding pad portion in FIG. 5;

FIG. 7 is a sectional view, taken along line VII-VII′, of the two-layer aluminum structure bonding pad portion in FIG. 5;

FIGS. 8A and 8B are diagrams showing the states at the time of bonding and after the bonding for explaining an impact of the bonding at a bonding pad portion;

FIG. 9 is a circuit diagram showing an equivalent circuit from a bonding pad to an input initial-stage circuit;

FIG. 10 is a plan view of a bonding pad portion provided with a terminal capacitance in a bonding pad region;

FIG. 11 is a plan view of a terminal capacitance provided in a bonding pad region;

FIG. 12 is a plan view of a bonding pad portion in which pillar-shaped leading interconnections are provided at two positions between a bonding pad and conductive patterns;

FIG. 13A is a plan view for explaining an impact of bonding at the related bonding pad portion and FIG. 13B is a perspective view showing a section taken along line B-B′ in FIG. 13A;

FIG. 14A is a plan view for explaining an impact of bonding at a bonding pad portion of this invention, FIG. 14B is a perspective view showing a section taken along line B-B′ in FIG. 14A, and FIG. 14C is a sectional view taken along line C-C′ in FIG. 14A;

FIG. 15A is a plan view of a bonding pad portion in which pillar-shaped leading interconnections are provided at two positions at both ends, and FIGS. 15B, 15C, and 15D are sectional views taken along line B-B′, line C-C′, and line D-D′ in FIG. 15A, respectively;

FIG. 16A is a plan view of a bonding pad portion in which pillar-shaped leading interconnections are provided at five positions, and FIGS. 16B, 16C, and 16D are sectional views taken along line B-B′, line C-C′, and line D-D′ in FIG. 16A, respectively;

FIG. 17A is a plan view of a bonding pad portion in which pillar-shaped leading interconnections are provided in the number of two at each of three positions, and FIGS. 17B, 17C, and 17D are sectional views taken along line B-B′, line C-C′, and line D-D′ in FIG. 17A, respectively;

FIG. 18A is a plan view of a bonding pad portion in which conductive patterns are provided in two rows and pillar-shaped leading interconnections are also provided in two rows, and FIGS. 18B, 18C, and 18D are sectional views taken along line B-B′, line C-C′, and line D-D′ in FIG. 18A, respectively;

FIG. 19A is a plan view of a bonding pad portion in which conductive patterns are provided in three rows and pillar-shaped leading interconnections are also provided in three rows, and FIGS. 19B, 19C, and 19D are sectional views taken along line B-B′, line C-C′, and line D-D′ in FIG. 19A, respectively;

FIG. 20 is a plan view of a bonding pad portion in which pillar-shaped capacitance leading interconnections are provided at two positions along each of three sides of a bonding pad;

FIG. 21A is a plan view of a bonding pad portion in which pillar-shaped capacitance leading interconnections are provided at three positions along each of three sides of a bonding pad, and FIGS. 21B and 21C are sectional views taken along line B-B′ and line C-C′ in FIG. 21A, respectively;

FIG. 22A is a plan view of a bonding pad portion in which pillar-shaped capacitance leading interconnections are provided at two positions along each of three sides of a bonding pad, and FIGS. 22B, 22C, and 22D are sectional views taken along line B-B′, line C-C′, and line D-D′ in FIG. 22A, respectively;

FIG. 23A is a plan view of a bonding pad portion in which pillar-shaped capacitance leading interconnections are provided at three positions along each of three sides of a bonding pad, and FIGS. 23B, 23C, and 23D are sectional views taken along line B-B′, line C-C′, and line D-D′ in FIG. 23A, respectively;

FIG. 24A is a plan view of a bonding pad portion in which pillar-shaped capacitance leading interconnections are provided at five positions along each of three sides of a bonding pad, and FIGS. 24B, 24C, and 24D are sectional views taken along line B-B′, line C-C′, and line D-D′ in FIG. 24A, respectively;

FIG. 25A is a plan view of a bonding pad portion in which pillar-shaped capacitance leading interconnections are provided in the number of two at each of two positions along each of three sides of a bonding pad, and FIGS. 25B, 25C, and 25D are sectional views taken along line B-B′, line C-C′, and line D-D′ in FIG. 25A, respectively;

FIG. 26A is a plan view of a bonding pad portion in which pillar-shaped capacitance leading interconnections are provided in the number of two at each of three positions along each of three sides of a bonding pad, and FIGS. 26B, 26C, and 26D are sectional views taken along line B-B′, line C-C′, and line D-D′ in FIG. 26A, respectively;

FIG. 27A is a plan view of a bonding pad portion in which conductive patterns are provided at two positions along each of three sides of a bonding pad and pillar-shaped capacitance leading interconnections are provided at both ends of each conductive pattern, and FIGS. 27B, 27C, and 27D are sectional views taken along line B-B′, line C-C′, and line D-D′ in FIG. 27A, respectively;

FIG. 28A is a plan view of a bonding pad portion in which conductive patterns are provided at three positions along each of three sides of a bonding pad and pillar-shaped capacitance leading interconnections are provided at both ends of each conductive pattern, and FIGS. 28B, 28C, and 28D are sectional views taken along line B-B′, line C-C′, and line D-D′ in FIG. 28A, respectively; and

FIG. 29 is a plan view showing various aluminum patterns of pillar-shaped leading interconnections.

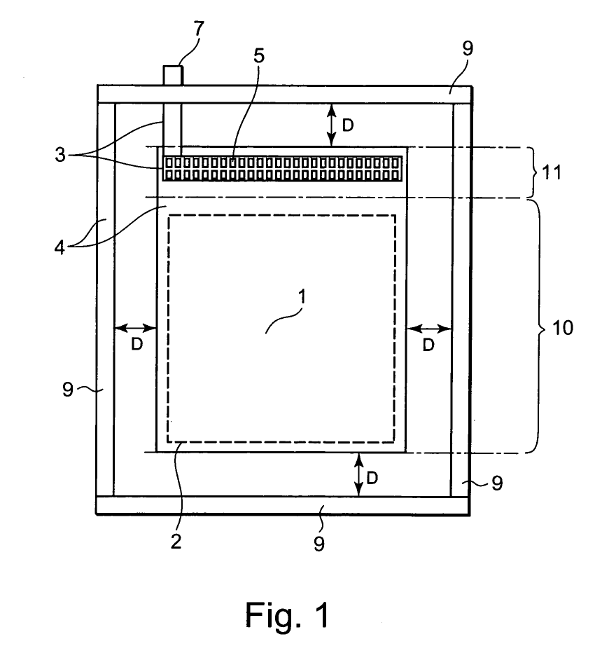

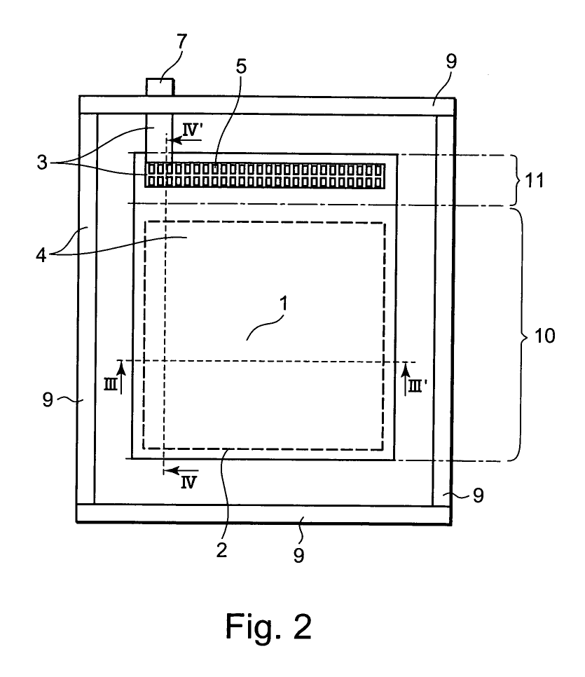

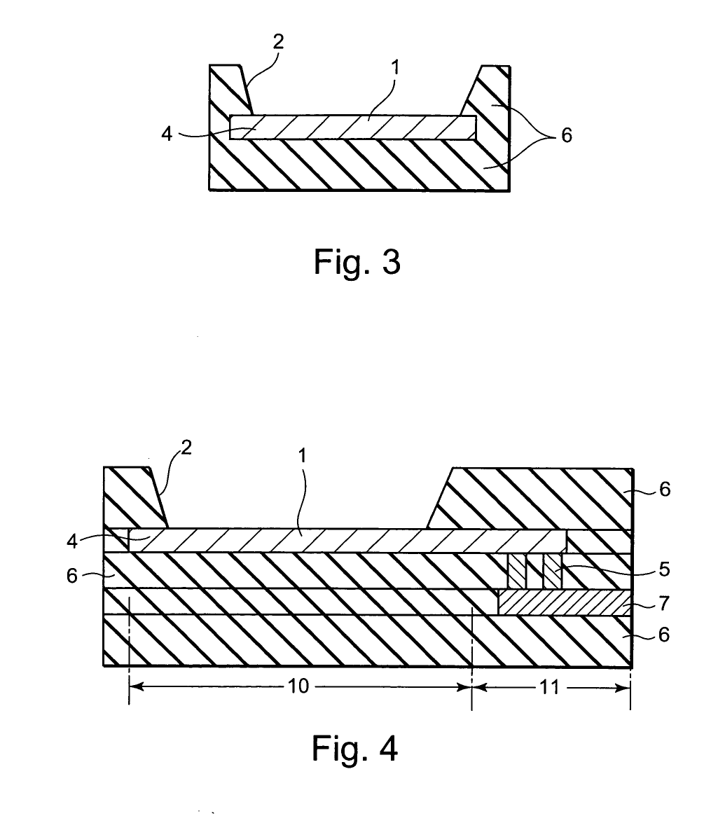

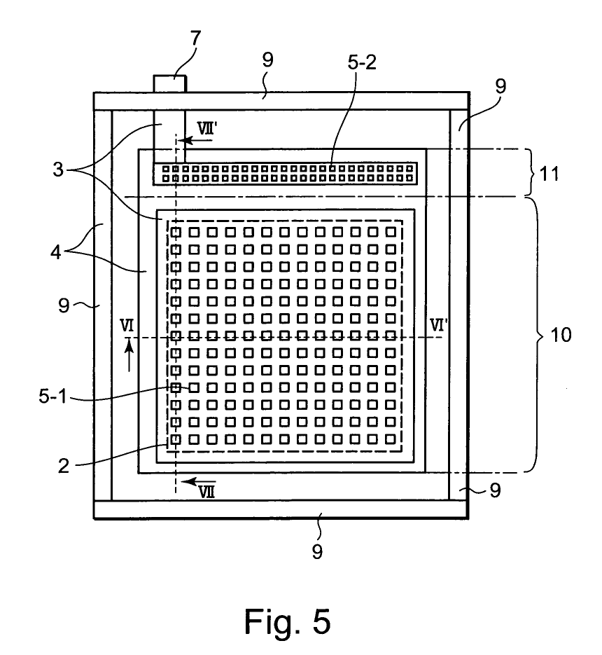

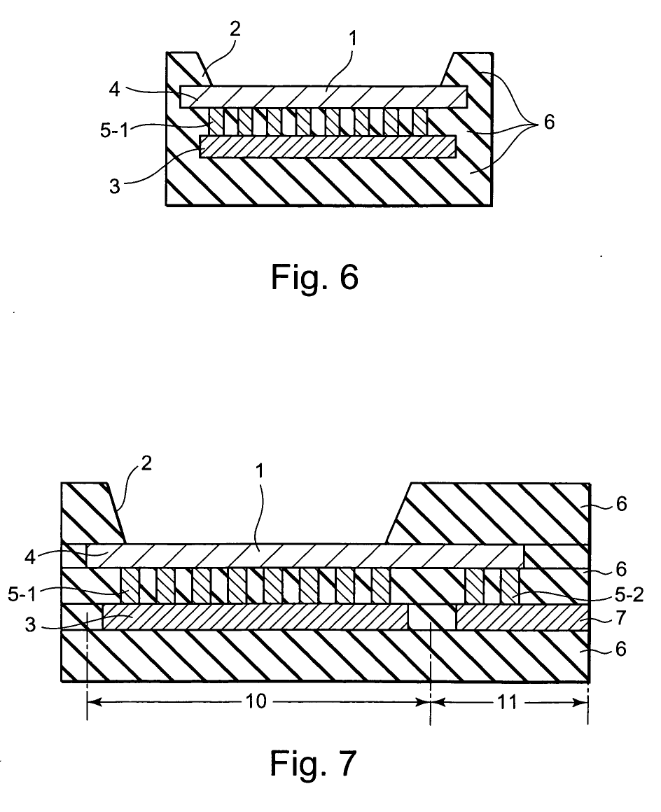

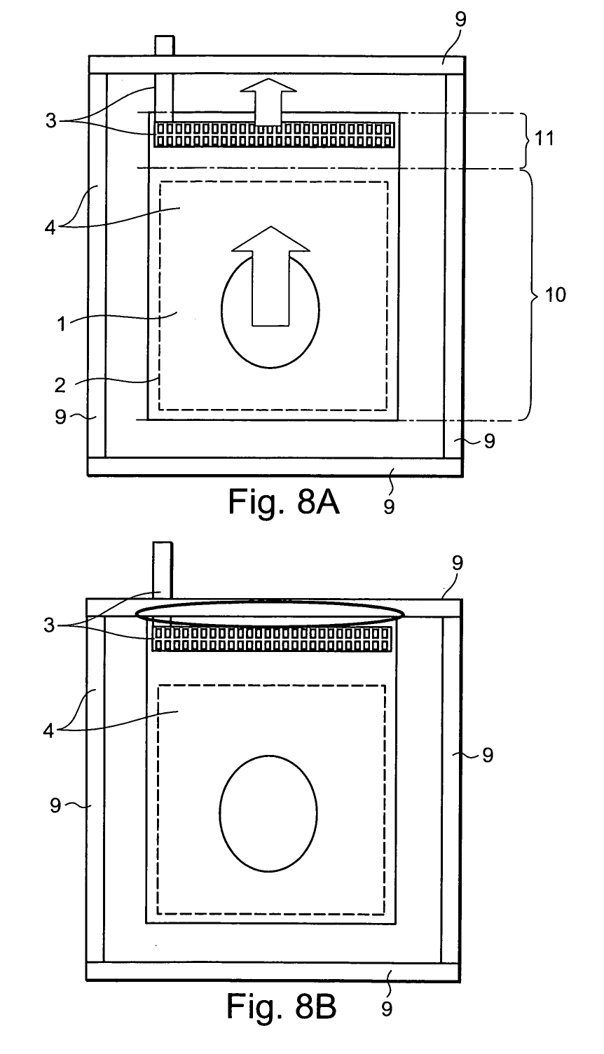

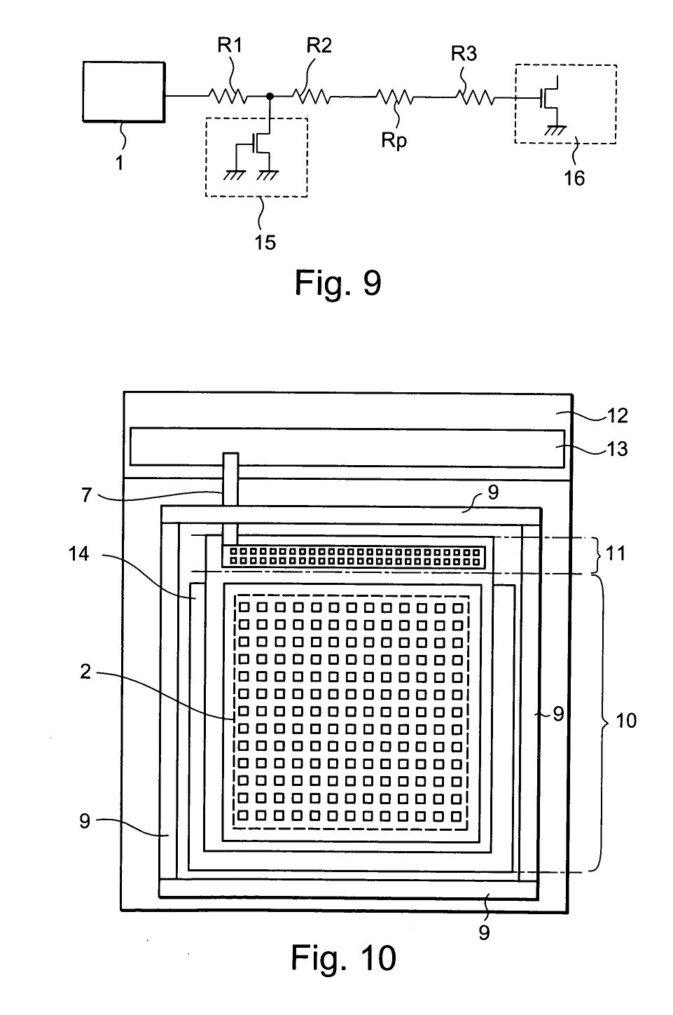

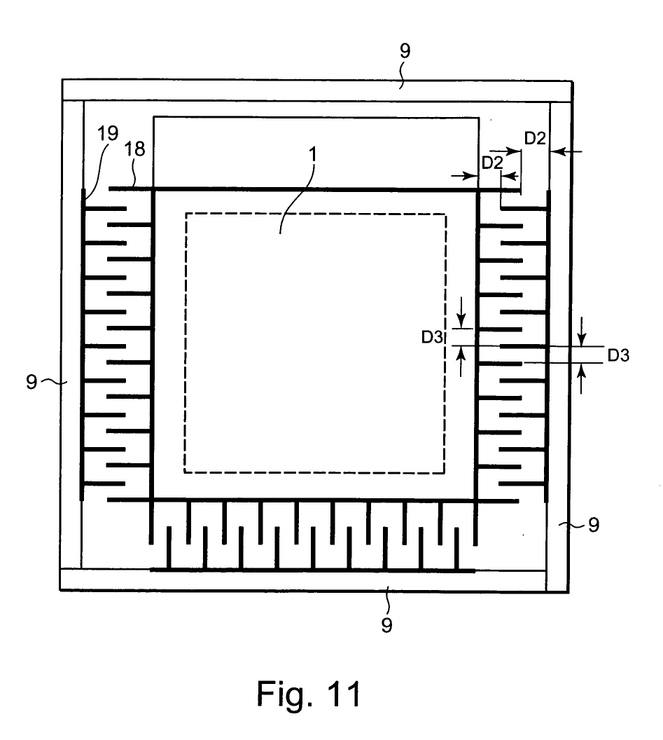

### DESCRIPTION OF THE PREFERRED EMBODIMENTS

Embodiments of this invention will be described in detail with reference to the drawings.

### First Exemplary Embodiments

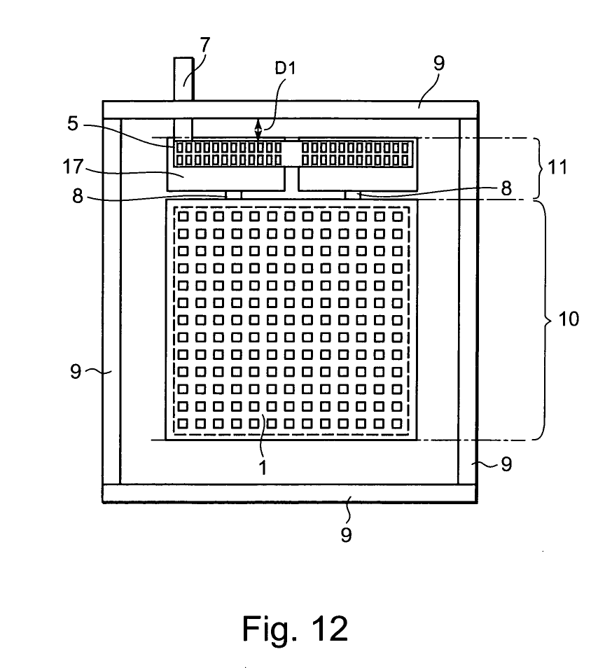

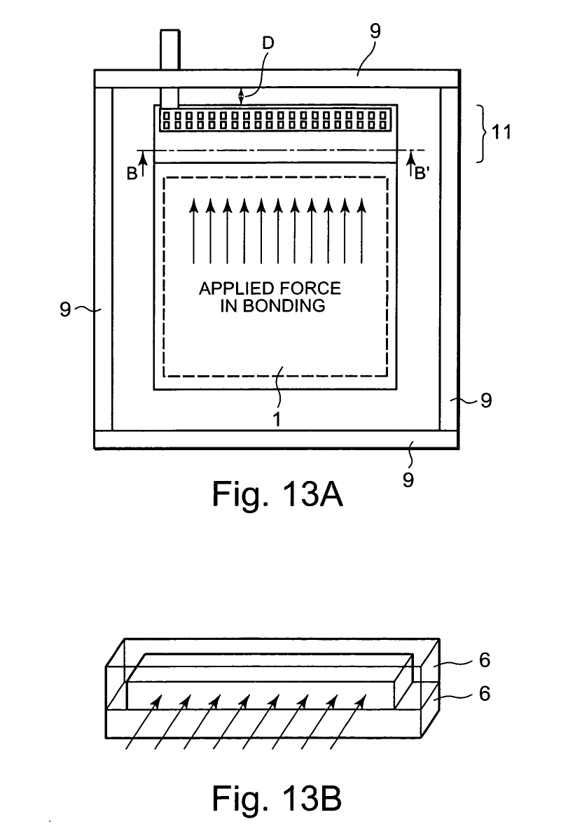

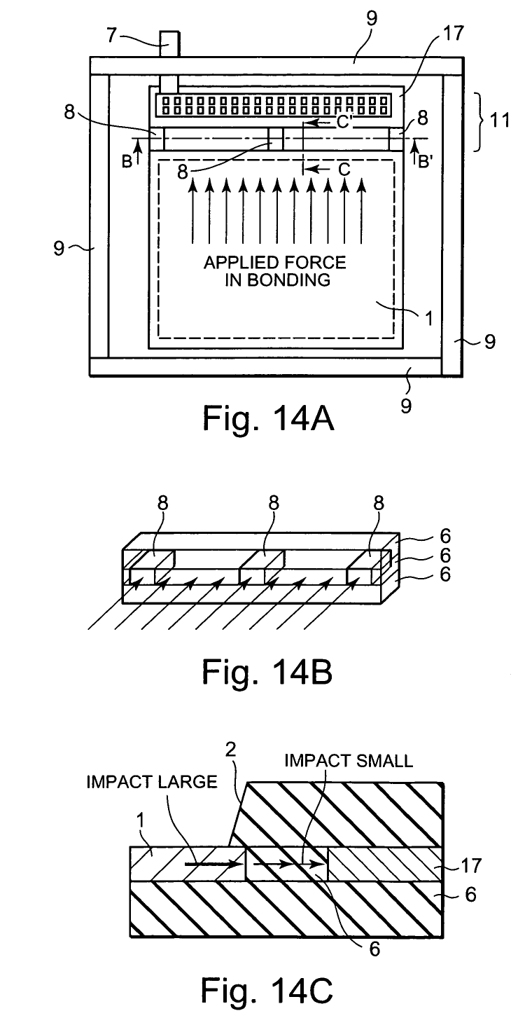

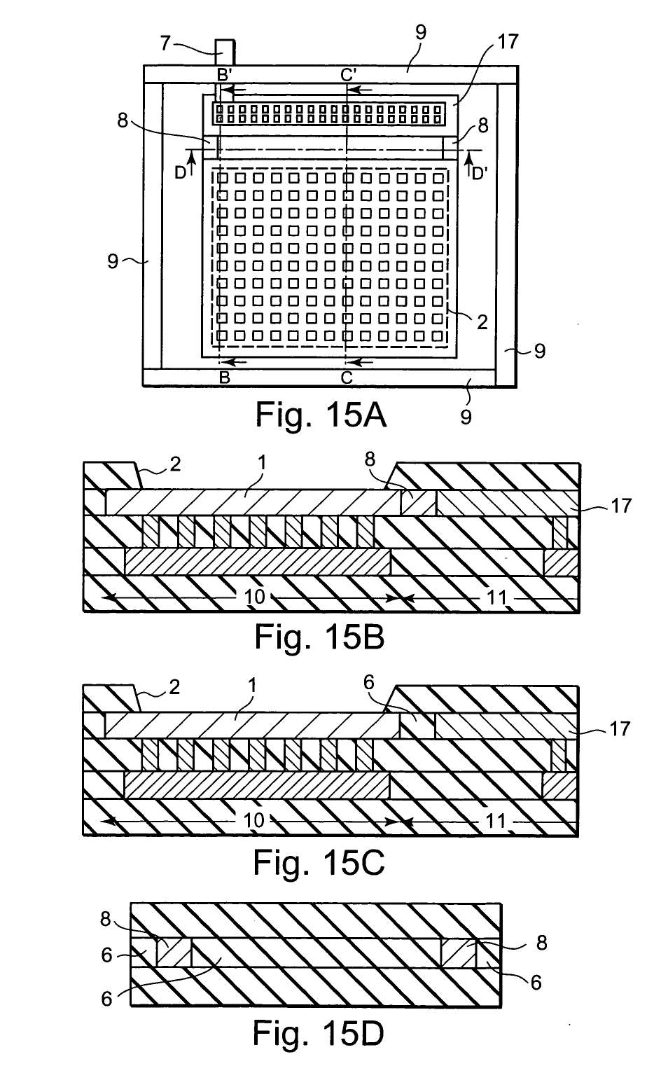

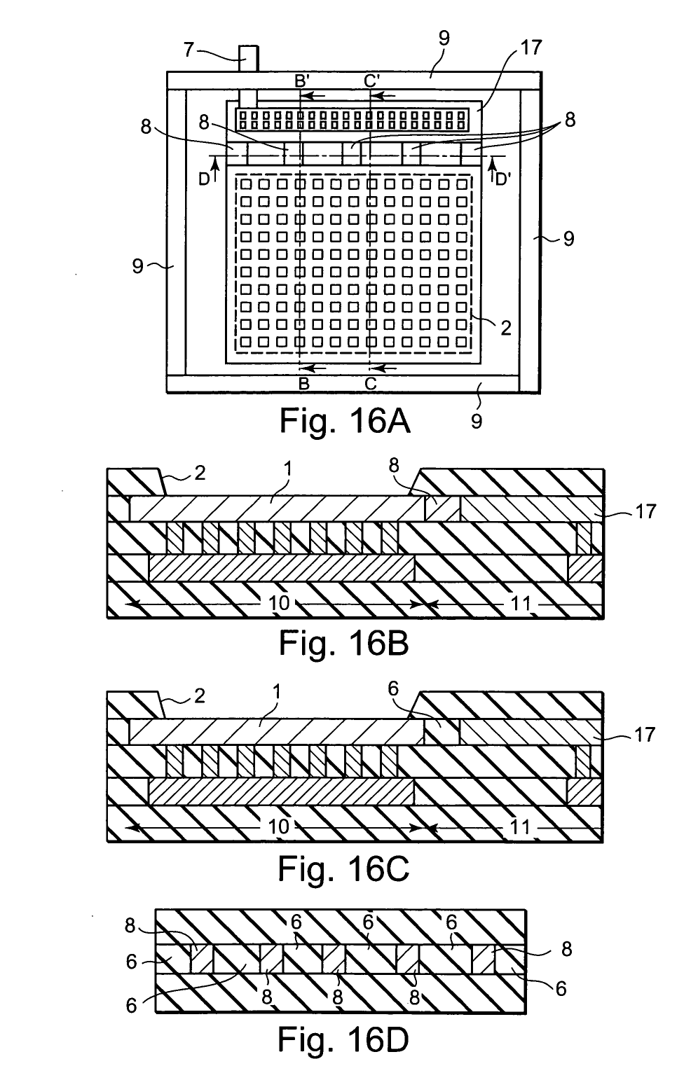

The first exemplary embodiments of this invention will be described in detail with reference to FIGS. 12 to 19D. In each embodiment, a conductive pattern/patterns is/are disposed between a bonding pad and an internal circuit connecting interconnection, and the conductive pattern/patterns and the bonding pad are connected to each other through leading interconnections. FIG. 12 is a plan view of a bonding pad portion in which leading interconnections are provided at two positions between a bonding pad and conductive patterns. FIG. 13A is a plan view for explaining an impact on bonding at the related bonding pad portion and FIG. 13B is a perspective view showing a section taken along line B-B′ in FIG. 13A. FIG. 14A is a plan view for explaining an impact on bonding at a bonding pad portion of this invention, FIG. 14B is a perspective view showing a section taken along line B-B′ in FIG. 14A, and FIG. 14C is a sectional view taken along line C-C′ in FIG. 14A. FIGS. 15A, 16A, . . . , and 19A are plan views of various bonding pad portions in each of which leading interconnections are provided between a bonding pad and a conductive pattern/patterns. FIGS. 15B, 16B, . . . , and 19B are sectional views taken along line B-B′ in FIGS. 15A, 16A, . . . , and 19A. FIGS. 15C, 16C, . . . , and 19C are sectional views taken along line C-C′ in FIGS. 15A, 16A, . . . , and 19A. FIGS. 15D, 16D, . . . , and 19D are sectional views taken along line D-D′ in FIGS. 15A, 16A, . . . , and 19A.

As shown in FIG. 12, two conductive patterns 17 connected to respective leading interconnections 8 from a bonding pad 1 are disposed in a leading region 11. The conductive patterns 17 have the same potential as that of the bonding pad 1. The conductive patterns 17 are arranged parallel to one side of the bonding pad 1 and the total length of the two conductive patterns 17 is substantially equal to the length of the side of the bonding pad 1. The total length of the conductive patterns 17 is not particularly limited and may be set shorter than the length of the side of the bonding pad 1. However, the total length of the conductive patterns 17 is preferably set equal to the length of the side of the bonding pad 1 because the area can be used most effectively in this case. The conductive patterns 17 are connected to a common first aluminum interconnection through contacts 5 and are further connected to an internal circuit through an internal circuit connecting interconnection 7.

The leading width of each leading interconnection 8 from the bonding pad 1 is shorter than the length of the side of the bonding pad 1 and the length of each conductive pattern 17. Therefore, the leading interconnection 8 will also be referred to as a “pillar-shaped leading interconnection” 8. Since the leading width of each pillar-shaped leading interconnection 8 is small, an insulating film is formed in most of the space between the bonding pad 1 and the conductive patterns 17 disposed parallel to each other. By means of the insulating film formed between the bonding pad 1 and the conductive patterns 17, the impact at the time of bonding is absorbed so that the impact to be transmitted to the conductive patterns 17 decreases.

The reason why the impact at the time of bonding is transmitted to the leading region 11 as a reduced force by the presence of the leading interconnections 8 and the insulating film will be explained with reference to FIGS. 13A and 13B and FIGS. 14A to 14C. At first, in the related structure shown in FIGS. 13A and 13B, the impact at the time of bonding is applied to the bonding pad 1 in a bonding direction (FIG. 13A). The applied impact is directly and uniformly transmitted to the leading region 11 (FIG. 13B). Therefore, the force transmitted to the leading region 11 is large so that interconnection offset tends to occur in the leading region 11.

In the structure of this invention shown in FIGS. 14A to 14C, the impact at the time of bonding is applied to a bonding pad 1 in a bonding direction (FIG. 14A). The applied impact is directly and uniformly transmitted to pillar-shaped leading interconnections 8 and an insulating film 6 (FIG. 14B). Because of the presence of the insulating film 6 between the pillar-shaped leading interconnections 8, the impact force is absorbed by the insulating film 6. Therefore, a reduced impact force after the absorption by the insulating film 6 is transmitted to a subsequent conductive pattern 17.

By providing the pillar-shaped leading interconnections 8, spaces (holes) are formed between the bonding pad 1 and the conductive pattern 17. The insulating film 6 in these spaces absorbs the impact force caused by the bonding. Since the impact force is reduced, it is possible to suppress movement or offset of the aluminum pattern of the conductive pattern 17. Herein, as a material of the insulating film serving to suppress the offset of the aluminum pattern, use can be made of an interlayer insulating film such as an oxide film or a nitride film.

By providing the pillar-shaped leading interconnections 8 between the bonding pad 1 and the conductive pattern 17 as described above, the impact applied to the bonding pad at the time of wire bonding is hardly transmitted to the conductive pattern 17. This makes it possible to reduce the distance to the pad peripheral aluminum interconnection around the bonding pad. Accordingly, it is not necessary to set a large distance D between the interconnection of the leading region 11 and the pad peripheral aluminum interconnection 9 as shown in FIG. 13A and, therefore, it is possible to make a design with a distance according to the process minimum standard.

Consequently, the layout pattern size around the bonding pad is reduced, thereby achieving a reduction in chip size. The pillar-shaped leading interconnections 8 are formed at two positions in FIG. 12 and at three positions in FIGS. 14A and 14B. The number of conductive patterns 17 and the number of pillar-shaped leading interconnections 8 are not particularly limited. The total width of the pillar-shaped leading interconnections 8 is determined to be equal to or greater than the width of the internal circuit connecting interconnection 7, thereby preventing the influence due to charge at the time of voltage application to the bonding pad.

This embodiment is characterized by disposing the conductive pattern/patterns 17 parallel to the bonding pad 1 and connecting it/them to the bonding pad 1 using the pillar-shaped leading interconnections 8. By providing the pillar-shaped leading interconnections 8, the impact at the time of wire bonding is absorbed to thereby suppress movement or offset of the aluminum pattern of the conductive pattern/patterns 17. This makes it possible to reduce the layout pattern size around the bonding pad, thereby achieving a reduction in chip size.

FIGS. 15A to 19D show the other exemplary embodiments in each of which a conductive pattern/patterns 17 is/are disposed parallel to a bonding pad 1 and connected to the bonding pad 1 through pillar-shaped leading interconnections 8. In each of these embodiments, the pillar-shaped leading interconnections 8 are provided at two or more positions along one side of the bonding pad 1. That is, a pad aluminum interconnection of a pad region and the conductive pattern/patterns of a leading region are connected to each other through the plurality of pillar-shaped leading interconnections 8.

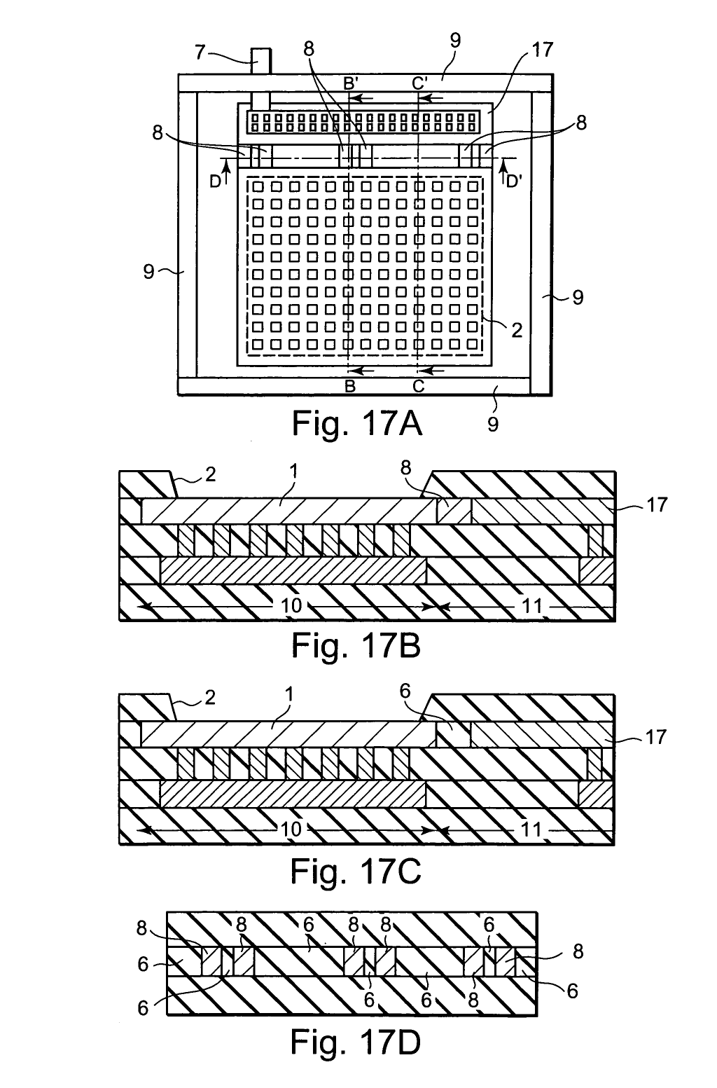

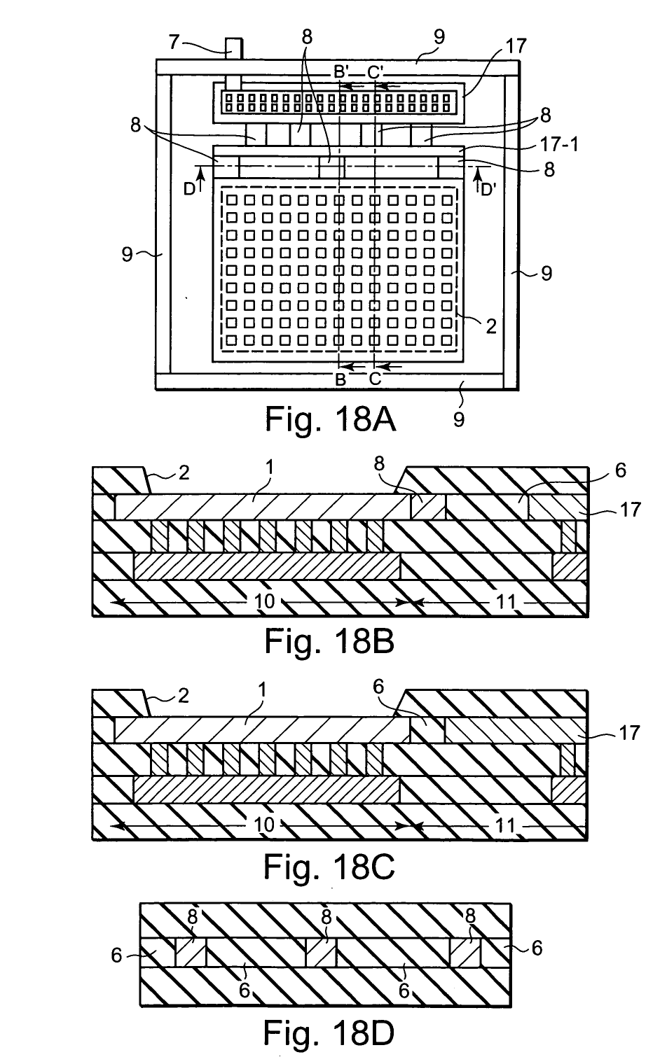

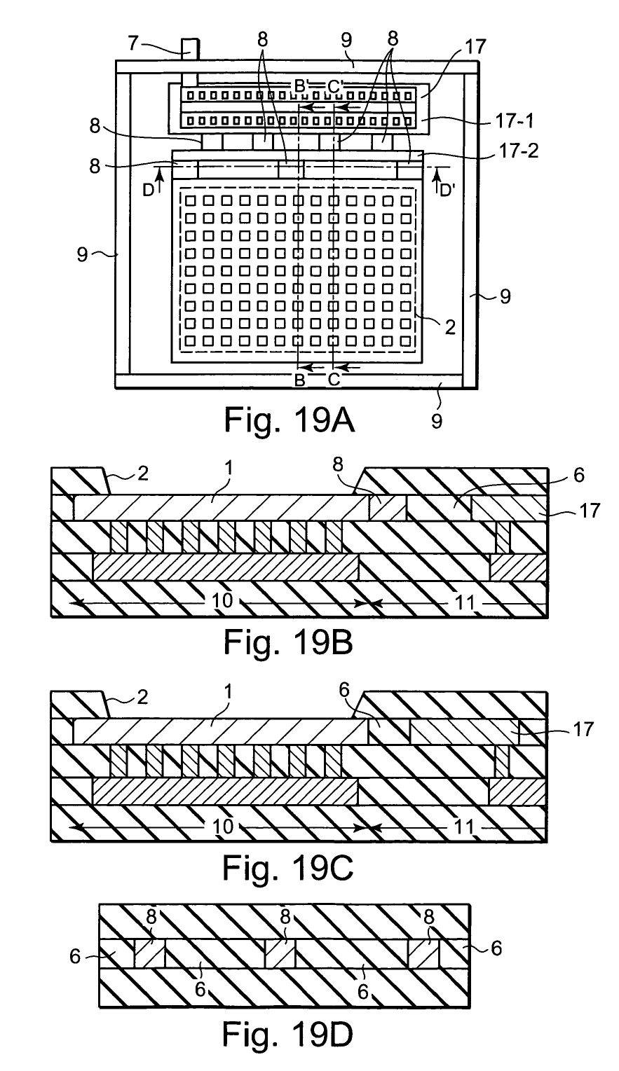

FIGS. 15A to 15D show the embodiment in which the pillar-shaped leading interconnections 8 are provided at two positions between the bonding pad 1 and the conductive pattern 17 at both ends thereof. FIGS. 16A to 16D show the embodiment in which the pillar-shaped leading interconnections 8 are provided at five positions. FIGS. 17A to 17D show the embodiment in which the pillar-shaped leading interconnections 8 are provided at three positions, each provided with the two pillar-shaped leading interconnections 8, and thus the six pillar-shaped leading interconnections 8 are provided in total. FIGS. 18A to 18D show the embodiment in which the conductive patterns 17 and 17-1 are provided in two rows and connection is made between the bonding pad 1 and the conductive pattern 17-1 and between the conductive pattern 17-1 and the conductive pattern 17 using the pillar-shaped leading interconnections 8. FIGS. 19A to 19D show the embodiment in which the conductive patterns 17, 17-1, and 17-2 are provided in three rows and connection is made between the bonding pad 1 and the conductive pattern 17-2, between the conductive pattern 17-2 and the conductive pattern 17-1, and between the conductive pattern 17-1 and the conductive pattern 17 using the pillar-shaped leading interconnections 8.

In each of the embodiments of FIGS. 18A to 18D and FIGS. 19A to 19D, the conductive pattern of the leading region is divided into the conductive patterns (or the additional conductive pattern is provided), and the pillar-shaped leading interconnections 8 and an insulating film are disposed therebetween. These are the embodiments in each of which two or three rows of the insulating film are provided so as to fill the spaces with the insulating film. By providing the plurality of rows comprising the pillar-shaped leading interconnections 8 and the insulating film, the impact at the time of bonding is further divided and weakened. With this structure, the impact path is divided so that the impact force reaching the farthest-end leading interconnection is further reduced. In the leading region designed according to the antenna standard and the ESD withstand voltage standard, it is also possible to dispose contacts 5 so as to be divided into a plurality of conductive patterns as in the manner shown in FIG. 19A. Even if the conductive patterns are disposed in the plurality of rows and the insulating film portions filling the spaces are increased as described above, the area does not largely increase because the design standard can be reduced.

In each embodiment, the aluminum pattern of the leading region is separated and this separated aluminum pattern, i.e. the conductive pattern, is disposed substantially parallel to the bonding pad. The conductive pattern and the bonding pad are connected to each other through the pillar-shaped leading interconnections. The space between the pad region and the leading region includes the pillar-shaped leading interconnections and the insulating film. The impact force at the time of bonding is absorbed by the insulating film, so that a reduced impact force after the absorption by the insulating film is transmitted to the subsequent conductive pattern. Therefore, it becomes possible to reduce the distance between the conductive pattern serving as an interconnection for leading and the pad peripheral aluminum interconnection, thereby achieving a reduction in chip size.

### Second Exemplary Embodiments

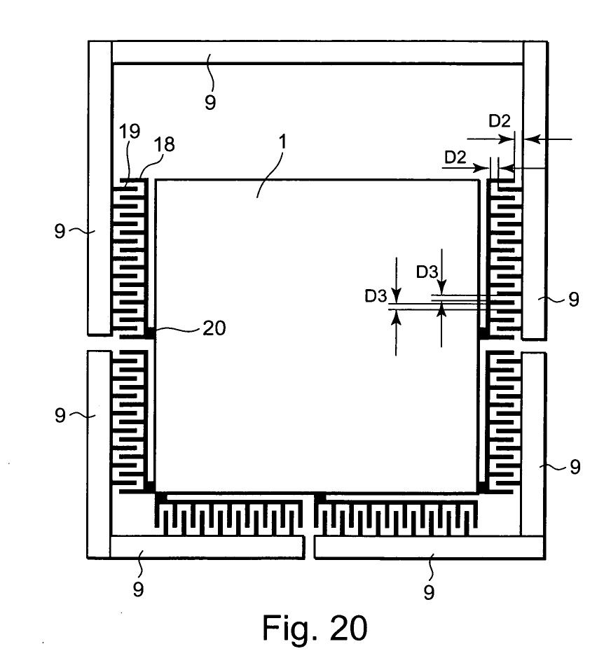

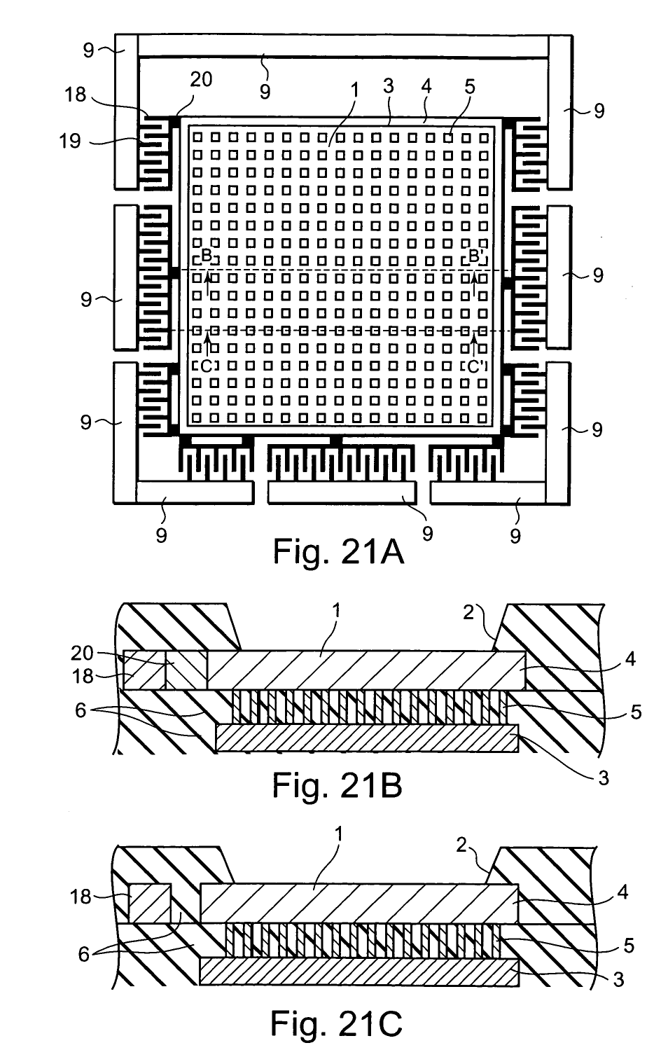

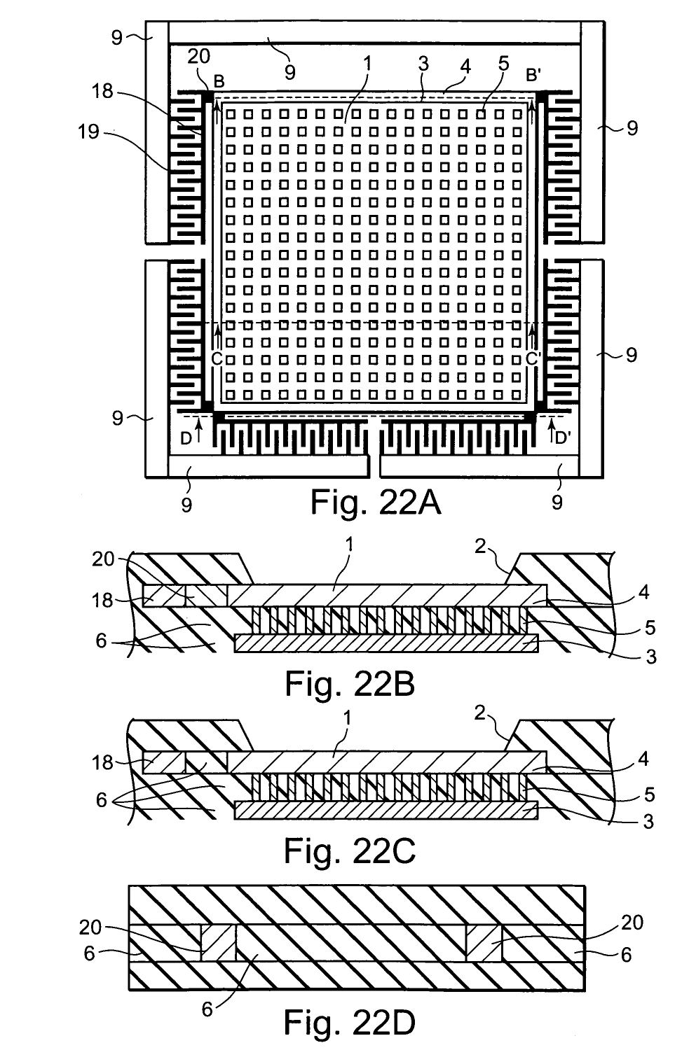

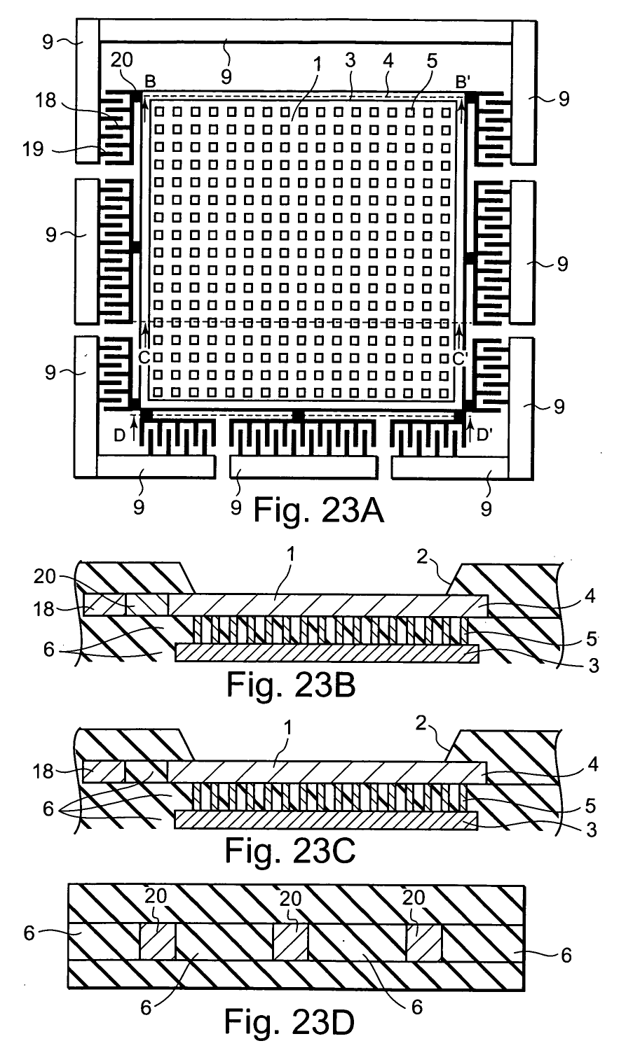

The second exemplary embodiments of this invention will be described in detail with reference to FIGS. 20 to 28D. In each embodiment, conductive patterns are applied to capacitance pad interconnections of a terminal capacitance provided in a bonding pad region. FIG. 20 is a plan view of a bonding pad portion in which pillar-shaped leading interconnections connected to conductive patterns, respectively, are provided at two positions along each of three sides of a bonding pad. FIG. 21A is a plan view of a bonding pad portion in which pillar-shaped leading interconnections are provided at three positions along each of three sides of a bonding pad, and FIGS. 21B and 21C are sectional views taken along line B-B′ and line C-C′ in FIG. 21A, respectively. FIGS. 22A, 23A, . . . , and 28A are plan views of various bonding pad portions in each of which pillar-shaped leading interconnections are provided at positions along each of three sides of a bonding pad. FIGS. 22B, 23B, . . . , and 28B are sectional views taken along line B-B′ in FIGS. 22A, 23A, . . . , and 28A. FIGS. 22C, 23C, . . . , and 28C are sectional views taken along line C-C′ in FIGS. 22A, 23A, . . . , and 28A. FIGS. 22D, 23D, . . . , and 28D are sectional views taken along line D-D′ in FIGS. 22A, 23A, . . . , and 28A.

FIG. 20 shows a layout pattern in which the terminal capacitance is formed in a pad region. The terminal capacitance is formed along three sides of a bonding pad 1 except its side to be connected to an internal circuit connecting interconnection. Conductive patterns 18 are disposed so as to extend from the bonding pad 1 through pillar-shaped capacitance leading interconnections 20, respectively. Herein, the conductive pattern 18 is an electrode forming the terminal capacitance and thus will also be referred to as a “capacitance pad interconnection” 18 hereinafter. The terminal capacitance is formed using the bonding pad 1 and a pad peripheral aluminum interconnection 9 as counter electrodes. As the pad peripheral aluminum interconnection 9, use can be made of a plurality of divided interconnections (potentials).

The pillar-shaped capacitance leading interconnections 20 are provided on the bonding pad 1 and the capacitance pad interconnections 18, each arranged in a comb shape, are connected to the leading interconnections 20, respectively. The capacitance pat interconnection 18 has the same potential as that of the bonding pad 1. The capacitance pad interconnection 18 has an interconnection parallel to the bonding pad 1 and teeth each extending from the interconnection parallel to the bonding pad 1 toward the pad peripheral interconnection 9. Capacitance counter-electrode interconnections (counter conductive patterns) 19 arranged in comb shapes together with the pad peripheral interconnection 9. The capacitance coutner-electrode interconnections 19 serve as the counter electrode. Thus, each of the capacitance counter-electrode interconnections 19 may have a potential different from that of the corresponding capacitance pad interconection 18. The capacitance counter-electrode interconnection 19 includes teeth each extending from the pad peripheral interconnection 9 toward the bonding pad 1. The teeth of the capacitance pad interconnections 18 and the teeth of the capacitance counter-electrode interconnections 19 are staggered in zigzag. The capacitance pad interconnections 18 and the capacitance counter-electrode interconnections 19 are the same-layer aluminum interconnections. As illustrated, the distance between the facing teeth of the comb-shaped interconnections 18 and 19 is given by D3 and the distance between the tip of the tooth of the comb-shaped interconnection 18 or 19 and the opposed interconnection is given by D2. The capacitance between the capacitance pad interconnection 18 and the capacitance counter-electrode interconnection 19 is determined by the distances D2 and D3.

The pillar-shaped capacitance leading interconnections 20 and an insulating film 6 are disposed between the bonding pad 1 and the capacitance pad interconnections 18. With this structure, the impact force at the time of bonding can be absorbed like in the first embodiments. This makes it possible to reduce the distances D2 and D3. By reducing the distances D2 and D3, the teeth of the capacitance pad interconnections 18 and the teeth of the capacitance counter-electrode interconnections 19 can be arranged in large numbers. By forming a large number of small-distance side-wall capacitances, there is obtained a terminal capacitance having a large capacitance value.

In FIG. 20, the pad peripheral aluminum interconnection 9 is divided into three interconnections with a configuration such that substantially equal capacitance values are achieved with respect to these three interconnections. The number of interconnections divided from the pad peripheral aluminum interconnection 9 is not particularly limited and can be arbitrarily set.

FIG. 21A is a plan view of a bonding pad portion according to one of the embodiments and FIGS. 21B and 21C are sectional views taken along line B-B′ and line C-C′ in FIG. 21A, respectively.

In FIG. 21A, a pad peripheral aluminum interconnection 9 is divided into six interconnections with a configuration such that substantially equal capacitance values are achieved with respect to these six interconnections.

In the B-B′ line sectional view of FIG. 21B, a bonding pad 1 is formed by a second aluminum layer 4. The bonding pad 1 is connected to a first aluminum layer 3 through contacts 5 and is connected to capacitance pad interconnections 18 through pillar-shaped capacitance leading interconnections 20.

In the C-C′ line sectional view of FIG. 21C, the bonding pad 1 is formed by the second aluminum layer 4 and is connected to the first aluminum layer 3 through the contacts 5. An insulating film 6 is disposed, instead of the pillar-shaped capacitance leading interconnection 20, adjacent to an end of the bonding pad 1 and the capacitance pad interconnection 18 is disposed adjacent to the insulating film 6. By this insulating film 6, the impact force at the time of bonding is reduced, so that a reduced impact force is transmitted to the capacitance pad interconnection 18.

FIGS. 22A to 28D show the other exemplary embodiments of this invention. In each of these embodiments, pillar-shaped capacitance leading interconnections 20 and capacitance pad interconnections 18 are provided along each of three sides of a bonding pad.

In FIGS. 22A to 22D, the pillar-shaped capacitance leading interconnections 20 and the capacitance pad interconnections 18 are respectively disposed at two positions along each of the three sides of the bonding pad. A pad peripheral aluminum interconnection 9 is divided into three interconnections with a configuration such that substantially equal capacitance values are achieved with respect to these three interconnections.

In FIGS. 23A to 23D, the pillar-shaped capacitance leading interconnections 20 and the capacitance pad interconnections 18 are respectively disposed at three positions along each of the three sides of the bonding pad. A pad peripheral aluminum interconnection 9 is divided into six interconnections with a configuration such that substantially equal capacitance values are achieved with respect to these six interconnections.

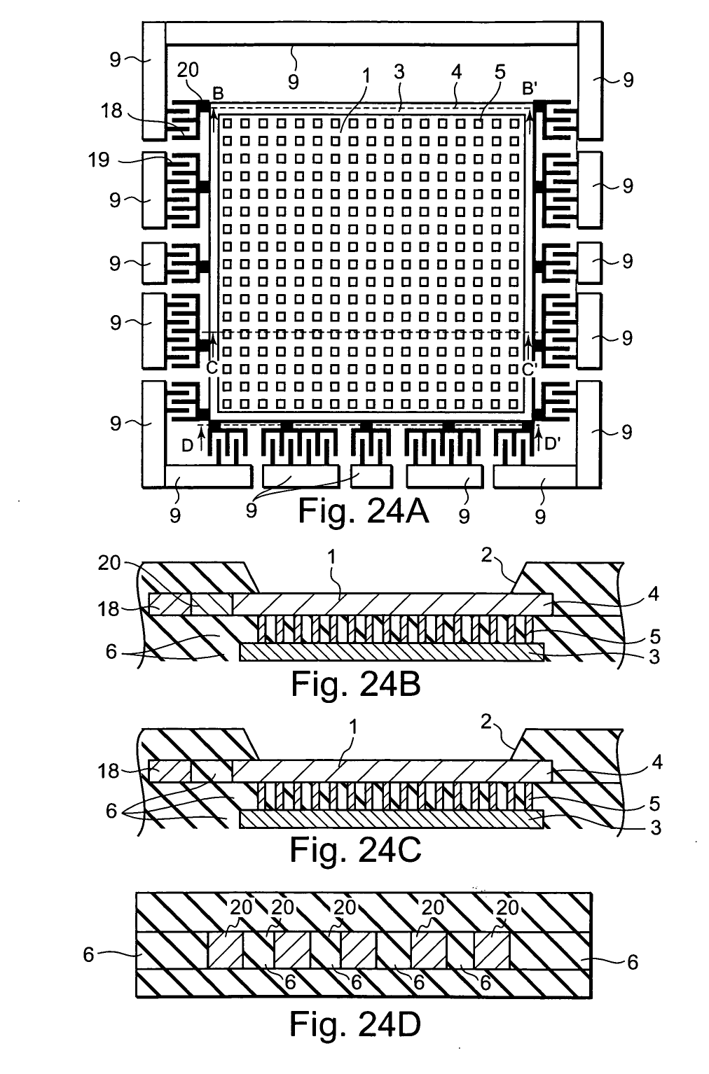

In FIGS. 24A to 24D, the pillar-shaped capacitance leading interconnections 20 and the capacitance pad interconnections 18 are respectively disposed at five positions along each of the three sides of the bonding pad. A pad peripheral aluminum interconnection 9 is divided into twelve interconnections with a configuration such that substantially equal capacitance values are achieved with respect to these twelve interconnections.

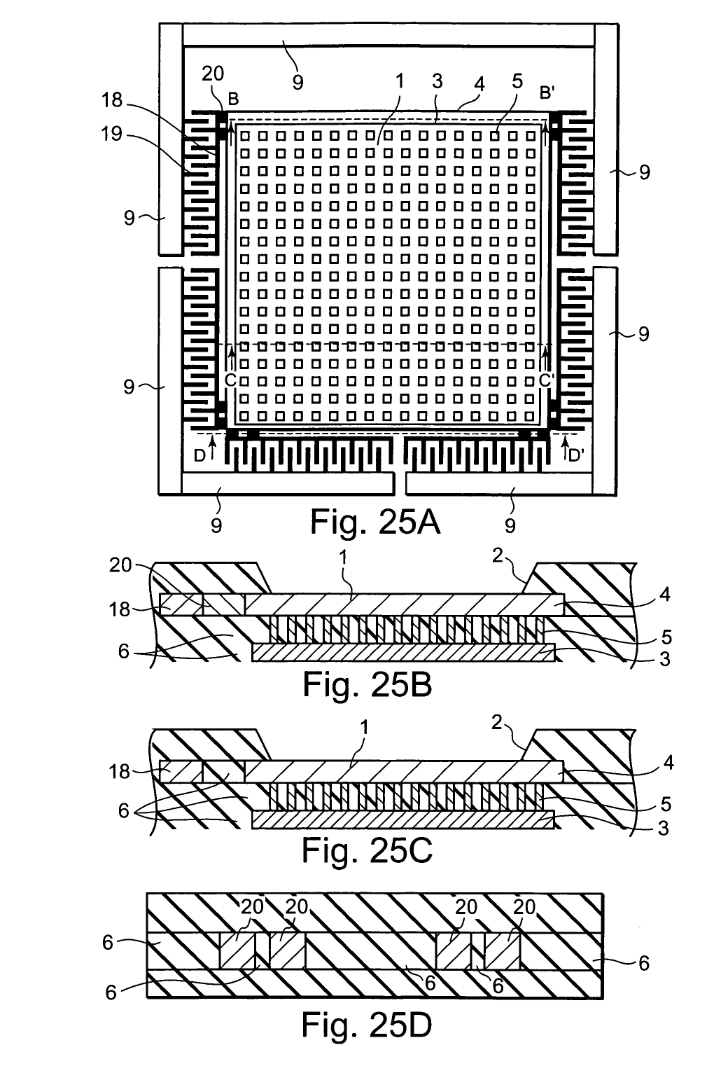

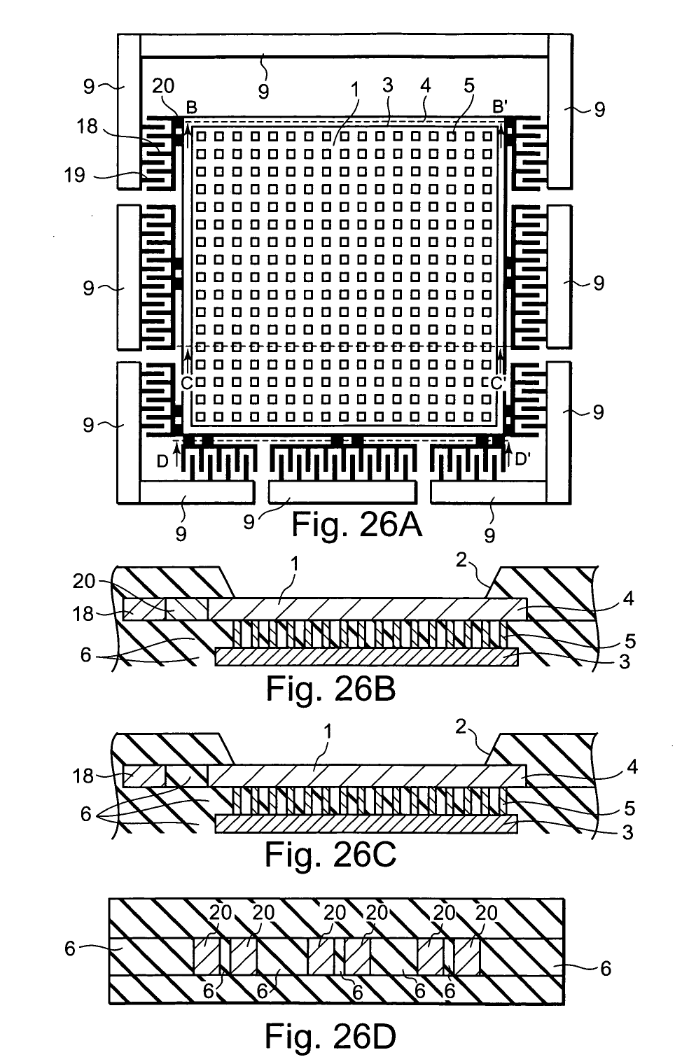

FIGS. 25A to 25D and FIGS. 26A to 26D show the embodiments in each of which the pillar-shaped capacitance leading interconnections 20 are provided in the number of two at one position for each of the capacitance pad interconnections 18.

In FIGS. 25A to 25D, the pillar-shaped capacitance leading interconnections 20 and the capacitance pad interconnections 18 are respectively disposed at two positions along each of the three sides of the bonding pad. The pillar-shaped capacitance leading interconnections 20 are provided in the number of two at each position. A pad peripheral aluminum interconnection 9 is divided into three interconnections with a configuration such that substantially equal capacitance values are achieved with respect to these three interconnections.

In FIGS. 26A to 26D, the pillar-shaped capacitance leading interconnections 20 and the capacitance pad interconnections 18 are respectively disposed at three positions along each of the three sides of the bonding pad. The pillar-shaped capacitance leading interconnections 20 are provided in the number of two at each position. A pad peripheral aluminum interconnection 9 is divided into six interconnections with a configuration such that substantially equal capacitance values are achieved with respect to these six interconnections.

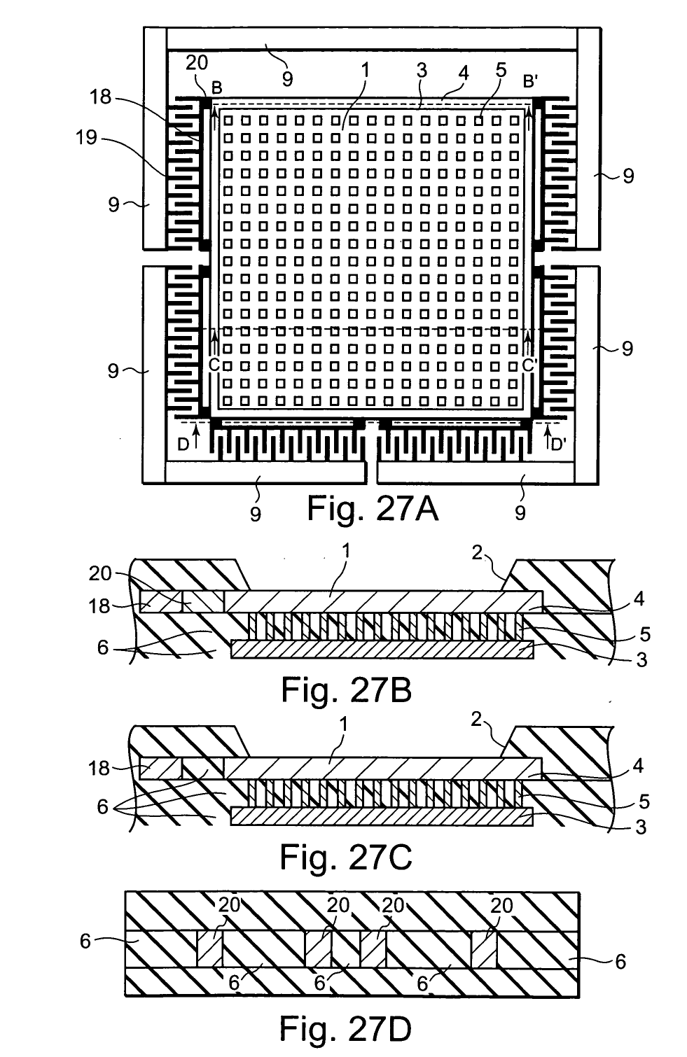

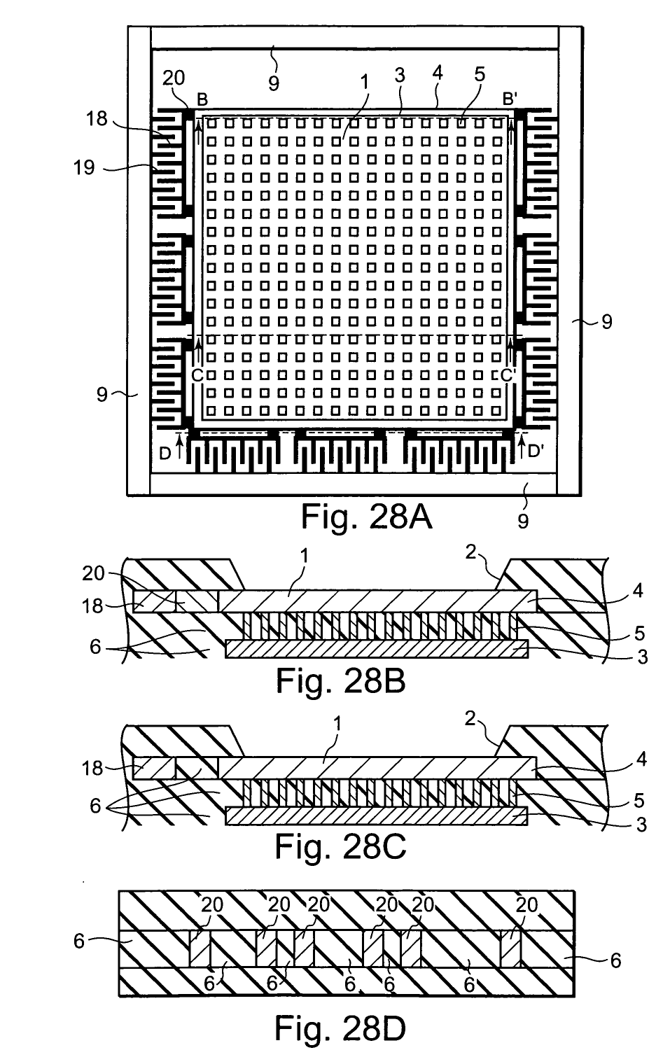

FIGS. 27A to 27D and FIGS. 28A to 28D show the embodiments in each of which the pillar-shaped capacitance leading interconnections 20 are disposed at both ends of each of the capacitance pad interconnections 18.

In FIGS. 27A to 27D, the capacitance pad interconnections 18 are disposed at two positions along each of the three sides of the bonding pad and the pillar-shaped capacitance leading interconnections 20 are provided at both ends of each of the capacitance pad interconnections 18. A pad peripheral aluminum interconnection 9 is divided into three interconnections with a configuration such that substantially equal capacitance values are achieved with respect to these three interconnections.

In FIGS. 28A to 28D, the capacitance pad interconnections 18 are disposed at three positions along each of the three sides of the bonding pad and the pillar-shaped capacitance leading interconnections 20 are provided at both ends of each of the capacitance pad interconnections 18.

In each of these embodiments, the comb-shaped capacitance pad interconnections are disposed parallel to the bonding pad and connected to the bonding pad through the pillar-shaped capacitance leading interconnections. The comb-shaped capacitance counter-electrode interconnections serving as the counter electrode are disposed on the pad peripheral aluminum interconnection. The pillar-shaped capacitance leading interconnections and the insulating film are disposed between the bonding pad and the capacitance pad interconnections. By disposing the pillar-shaped capacitance leading interconnections and the insulating film, the impact force at the time of bonding is absorbed by the insulating film. Thus, a reduced impact force after the absorption by the insulating film is transmitted to the subsequent comb-shaped capacitance pad interconnections. Therefore, it becomes possible to reduce the distance between the capacitance pad interconnections and the corresponding capacitance counter-electrode interconnections, thereby achieving a reduction in chip size.

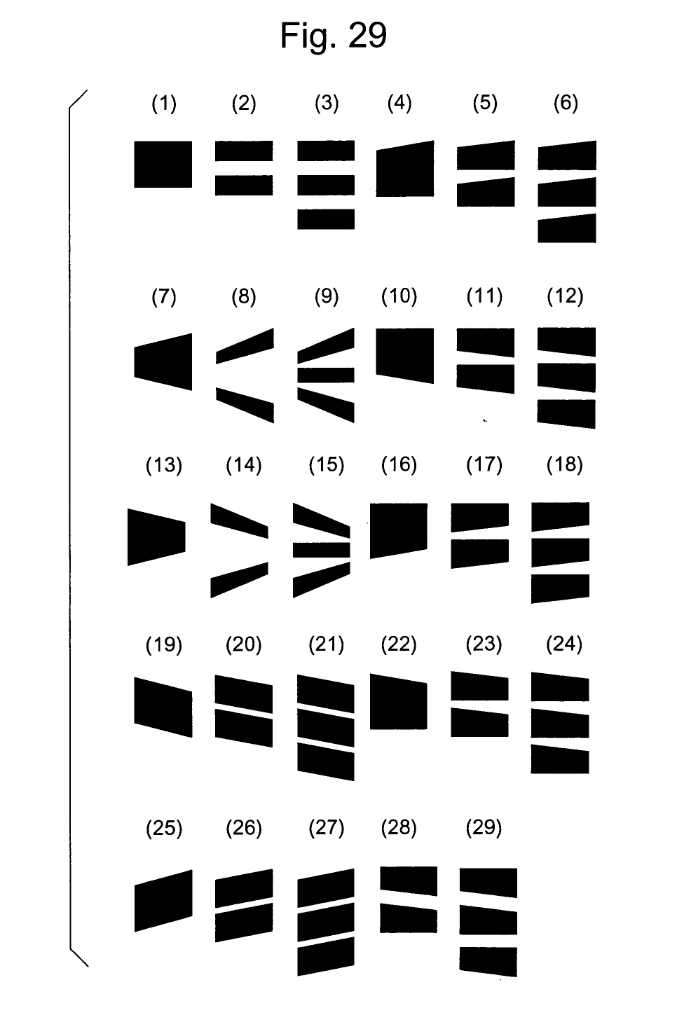

Next, referring to FIG. 29, a description will be given of examples of aluminum patterns as pillar-shaped (capacitance) leading interconnections that can be employed in the foregoing first and second embodiments.

(1) to (29) shown in FIG. 29 are plan views each corresponding to a pattern for one pillar-shaped (capacitance) leading interconnection in the foregoing description. The bonding pad is located on the right or left side of each figure and the conductive pattern or the capacitance pad interconnection is located on the left or right side thereof.

By selecting the proper pattern from such various aluminum patterns, there are obtained pillar-shaped (capacitance) leading interconnections adaptable to various force directions at the time of bonding. That is, using these pillar-shaped aluminum patterns as pillar-shaped leading interconnections in the first embodiments and pillar-shaped (capacitance) leading interconnections in the second embodiments, it becomes possible to reliably reduce the impact force at the time of bonding. By reducing the impact force at the time of bonding, it is possible to reduce the distance between the leading interconnection and the pad peripheral aluminum interconnection and the distance between the capacitance pad interconnection and the pad peripheral aluminum interconnection forming the terminal capacitance. By reducing the design standard around the pad, there is obtained a small-size pad structure and thus there is obtained a small-chip-size semiconductor integrated circuit having the small pad structure.

While this invention has been described in detail based on the embodiments, the invention is not to be limited thereto, but can be embodied with various changes within a range not departing from the gist of the invention and, naturally, those modifications are also included in this invention.

What is claimed is:

1. A semiconductor integrated circuit comprising:
a bonding pad;
a conductive pattern disposed in the vicinity of said bonding pad; and
a leading interconnection connecting said conductive pattern to said bonding pad.

2. A semiconductor integrated circuit according to claim 1, wherein an insulating film is provided, in addition to said leading interconnection, between said conductive pattern and a side of said bonding pad so as to suppress offset of said conductive pattern.

3. A semiconductor integrated circuit according to claim 2, wherein said conductive pattern has a length substantially equal to that of the side of said bonding pad and is disposed parallel to the side of said bonding pad.

4. A semiconductor integrated circuit according to claim 3, wherein said leading interconnection is provided at one or more positions between said conductive pattern and the side of said bonding pad.

5. A semiconductor integrated circuit according to claim 3, wherein an additional conductive pattern is provided in the vicinity of said conductive pattern and said conductive pattern is connected to said additional conductive pattern through an additional leading interconnection.

6. A semiconductor integrated circuit according to claim 3, wherein said conductive pattern is further connected to an internal circuit connecting interconnection connected to an internal circuit and said leading interconnection has a width equal to or greater than that of said internal circuit connecting interconnection.

7. A semiconductor integrated circuit according to claim 3, further comprising a counter conductive pattern in the vicinity of said conductive pattern, wherein a terminal capacitance is formed between said conductive pattern and said counter conductive pattern.

8. A semiconductor integrated circuit according to claim 7, wherein said conductive pattern and said counter conductive pattern are each arranged in a comb shape having teeth and the teeth of said conductive pattern and the teeth of said counter conductive pattern are staggered in zigzag.
